(19) United States
(12) Patent Application Publication
(10) Pub. No.: US 2014/0060650 A1
(43) Pub. Date: Mar. 6, 2014

(54) POLYHEDRAL OLIGOMERIC SILSESQUIOXANE ORGANIC/POLYMERIC DYADS AND ITS APPLICATION FOR ORGANIC PHOTOVOLTAIC CELLS

(71) Applicants: Stephen Z.D. Cheng, Richfield, OH (US); Wenbin Zhang, Hudson, OH (US); Xiong Gong, Akron, OH (US)

(72) Inventors: Stephen Z.D. Cheng, Richfield, OH (US); Wenbin Zhang, Hudson, OH (US); Xiong Gong, Akron, OH (US)

(73) Assignee: THE UNIVERSITY OF AKRON, Akron, OH (US)

(21) Appl. No.: 14/006,373

(22) PCT Filed: Mar. 21, 2012
(86) PCT No.: PCT/US12/29903

§ 371 Date: Oct. 31, 2013

Related U.S. Application Data
(60) Provisional application No. 61/454,715, filed on Mar. 21, 2011.

(51) Int. Cl. H01L 51/42; H01L 51/00

(52) U.S. Cl. CPC H01L 51/424; H01L 51/0036; H01L 51/0046
USPC 136/263

(57) ABSTRACT

A bulk heterojuction for a photovoltaic cell includes a polyhedral oligomeric silsesquioxane (POSS) functionalized electron acceptor or electron donor or both. The electron donor may be selected from conjugated polymers and the electron donor may be selected from fullerenes and fullerene derivatives.

### CROSS-REFERENCE TO RELATED APPLICATION

This application claims priority from International Application Serial No. PCT/US2012/029903 filed Mar. 21, 2012 which claims priority from U.S. Provisional Patent Application No. 61/454,715 filed on Mar. 21, 2011, the contents of which are incorporated herein by reference.

### FIELD OF THE INVENTION

The present invention generally relates to photovoltaic cells. More particularly the present invention relates to organic photovoltaic cells, and, more specifically to bulk heterojunction organic photovoltaic cells. The present invention provides new photoactive layer blends useful in bulk heterojunction organic photovoltaic cells.

### BACKGROUND OF THE INVENTION

In the recent years, there has been a growing interest of developing bulk heterojunction (BHJ) organic photovoltaic cells. This class of technologies offers a low-cost, large-area, flexible, light-weight, clean, and quiet alternative energy source for both indoor and outdoor applications.

A contemporary BHJ organic photovoltaic cell contains an electron donor (D) and an electron acceptor (A) in the active layer. The electron donor is typically a blend of organic/polymeric materials (typically conjugated polymer(s)) as the electron donor, with fullerene and fullerene derivatives as the electron acceptor. Three operational mechanisms have been recognized to determine how efficient BHJ organic photovoltaic cells are able to generate electricity: absorption of a photon by the electron donor and the electron acceptor, leading to the formation of the exciton (electron-hole pairs); exciton diffusion at donor/acceptor interface resulting in charge separation; and charge transport within the donor and the acceptor to the respective electrodes. In order to achieve high power conversion efficiencies (PCEs), both the donor and acceptor should (1) absorb more photons, (2) form a bicontinous network structure with large interface, (3) posses efficient photo-induced charge transfer at the donor/acceptor interface and (4) form separate channels for charge carriers to be transported to respective electrodes.

Power conversion efficiencies as high as 6-8% have been reported for BHJ organic photovoltaic cells in response to solar AM1.5 radiation. In order to attain PCEs over 10%, BHJ materials capable of generating higher short circuit current (Jsc) and larger open circuit voltage (Voc) are required. One approach to increase Jsc and Voc is to develop low-band-gap organic/polymer materials with deeper HOMO (Highest Occupied Molecular Orbital) energies. An alternative approach is to develop new electron acceptors with higher LUMO (Lowest Unoccupied Molecular Orbital) energies.

### SUMMARY OF THE INVENTION

In one embodiment, the present invention provides improvements in a bulk heterojunction photovoltaic cell having a bulk heterojunction that is a mixture of an electron donor and an electron acceptor. The improvement comprises functionalizing either the electron donor or the electron acceptor or both with polyhedral oligomeric silsesquioxane (POSS).

In other embodiments, the present invention provides improvements in a bulk heterojunction photovoltaic cell as in paragraph [0005], wherein the electron acceptor is a fullerene or fullerene derivative.

In other embodiments, the present invention provides improvements in a bulk heterojunction photovoltaic cell as any of paragraphs [0005] through [0006], wherein the electron donor is a conjugated polymer.

In other embodiments, the present invention provides improvements in a bulk heterojunction photovoltaic cell as any of paragraphs [0005] through [0007], wherein the electron acceptor is a fullerene or fullerene derivative and the electron donor is a conjugated polymer.

In other embodiments, the present invention provides improvements in a bulk heterojunction photovoltaic cell as any of paragraphs [0005] through [0008], wherein the electron acceptor is functionalized with POSS.

In other embodiments, the present invention provides improvements in a bulk heterojunction photovoltaic cell as any of paragraphs [0005] through [0009], wherein the electron donor is functionalized with POSS.

In other embodiments, the present invention provides improvements in a bulk heterojunction photovoltaic cell as any of paragraphs [0005] through [0010], wherein the electron acceptor is functionalized with POSS and the electron donor is functionalized with POSS.

In other embodiments, the present invention provides improvements in a bulk heterojunction photovoltaic cell as any of paragraphs [0005] through [0011], wherein the electron acceptor is a fullerene or fullerene derivative, and the electron donor is a POSS-functionalized conjugated polymer, the conjugated polymer selected from poly[[[(2-ethylhexyl)oxy]methoxy-1,4-phenylene]-1,2-ethenediyl] (MEHPPV), polythiophene (PT), and poly[(4,4′-bis(2-ethylhexyl)dithieno[3,2-b:2′,3′-d]silole)-2,6-diyl-alt-(4,7-bis(2-thienyl)-2,1,3-benzothiadiazole)-5,5′-diyl] (SiPCPDTBT).

In other embodiments, the present invention provides improvements in a bulk heterojunction photovoltaic cell as any of paragraphs [0005] through [0012], wherein the electron donor is a conjugated polymer, and the electron acceptor is a POSS-functionalized fullerene or fullerene derivative, the fullerene or fullerene derivative selected from [60]fullerene, [70]fullerene, and [84]fullerene and derivatives thereof.

In other embodiments, the present invention provides improvements in a bulk heterojunction photovoltaic cell as any of paragraphs [0005] through [0013], wherein the electron donor is a POSS-functionalized conjugated polymer, the conjugated polymer selected from poly[[[(2-ethylhexyl)oxy]methoxy-1,4-phenylene]-1,2-ethenediyl] (MEHPPV), polythiophene (PT), poly(3,4-ethylenedioxythiophene) (PEDOT), and poly[(4,4′-bis(2-ethylhexyl)dithieno[3,2-b:2′,3′-d]silole)-2,6-diyl-alt-(4,7-bis(2-thienyl)-2,1,3-benzothiadiazole)-5,5′-diyl] (SiPCPDTBT), and the electron donor is a conjugated polymer, and the electron acceptor is a POSS-functionalized fullerene or fullerene derivative, the fullerene or fullerene derivative selected from [60]fullerene, [70]fullerene, and [84]fullerene and derivatives thereof.

### BRIEF DESCRIPTION OF THE DRAWINGS

FIG. 1 is a general schematic of a bulk heterojunction photovoltaic cell;

FIG. 2 is a graph of the compacitanze-voltage (CV) measurements of a POSS-functionalized fullerene, particularly C₆₀;

FIGS. 3 and 4 is a graph of the time-resolved photo-induced absorption measurement of pristine conjugated polymer, Si-ZZ50 and composite of Si-ZZ50: POSS-C60;

FIGS. 5 and 6 are graphs of the absorption and photoluminescent (PL) spectra of MEHPPV-POSS and MEHPPV in solution (FIG. 5) and as fin films (FIG. 6);

FIG. 7 is a comparison of the open-circuit voltage (V_{OC}) of organic photovoltaic cells made with MEHPPV:PCBM and MEHPPV-POSS:PCBM;

FIG. 8 shows the inverted device structure of an organic photovoltaic cell made with conjugated polymer Si-ZZ50 blended with POSS-C₆₀; and

FIG. 9 provides a graph comparing the V_{OC} of polymer solar cells including bulk heterojunctions of Si-ZZ50:PCBM and Si-ZZ50:POSS-PCBM.

### DETAILED DESCRIPTION OF ILLUSTRATIVE EMBODIMENTS

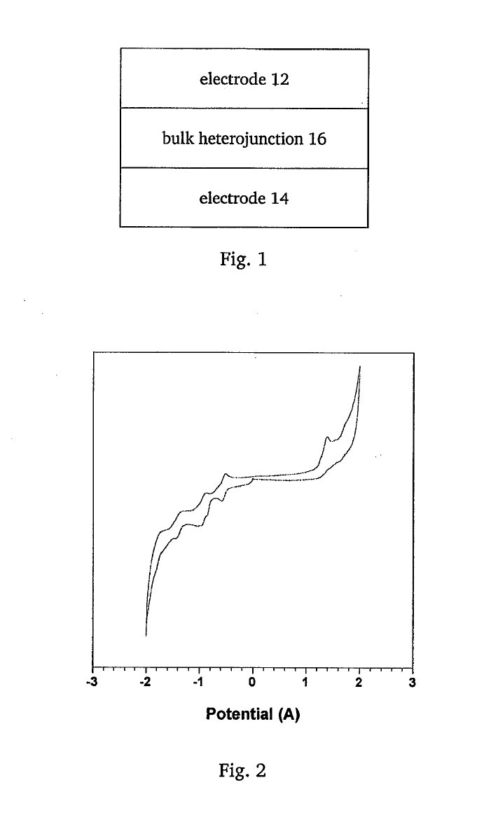

The present invention teaches the beneficial employment of polyhedral oligomeric silsesquioxane (POSS) in the active layer of a bulk heterojunction organic photovoltaic cell. A general schematic of a bulk heterojunction photovoltaic cell is shown in FIG. 1 and designated by the numeral 10. Therein a mixture of an electron donor and an electron acceptor, called the heterojunction, is sandwiched between a first electrode 12 and a second electrode 14. The heterojunction 16 is typically a polymer blend, but polymer and fullerene mixtures have also been found acceptable. The polymers employed are usually highly conjugated, as are the fullerenes. The present invention improves the art through the functionalization of one or more of the polymer or fullerene components of the heterojunction mixture with POSS.

In accordance with this invention, the heterojunction 16 can be provided by the following mixtures: (1) a POSS-functionalized conjugated polymer blended with a fullerene or a fullerene derivative, (2) a conjugated polymer blended with a POSS-functionalized fullerene or a POSS-functionalized fullerene derivative and (3) a POSS-functionalized conjugated polymer blended with POSS-functionalized fullerene or a POSS-functionalized fullerene derivative. In embodiments with POSS-functionalized conjugated polymer, the conjugated polymer is end functionalized, and may be functionalized with POSS at either one or both ends. The fullerenes and fullerene derivatives can also be functionalized with one or more POSS with same or different peripheryl functional groups.

The POSS has the general formula RₙSiₙO_{1.5n} and the polyhedral cage-like structures take the following forms:

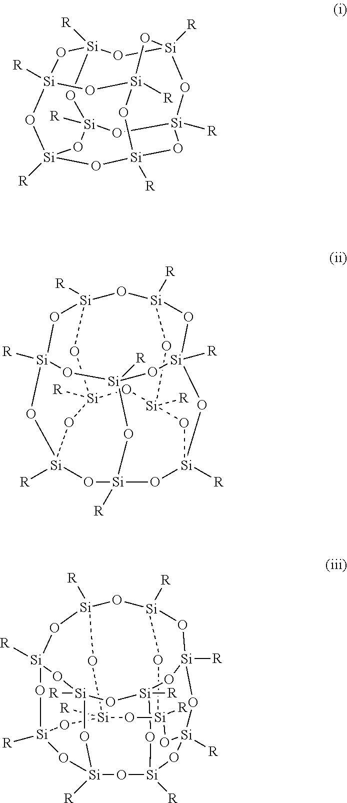

wherein the R is chosen from hydrogen and alkyl, alkene, aryl, and arylene groups. Some common groups include methyl, isobutyl, cyclopentyl, cyclohexyl, phenyl, and aniline.

A variety of functional groups can be added, either introduced before the POSS cage formation or obtained post POSS cage formation. Functional groups include branched or linear alkyl chains (e.g., —(CH2)nCH3), fluorinated alkyl chains (e.g., —CH2CH2(CF2)nCF3), hydrophilic groups, aromatic groups (e.g., (un)substituted phenyls), and hydrophilic groups (e.g., —CH2CH2SCH2COOH, and —CH2CH2SCH2CHOHCH2OH).

It is appreciated that one or more corner groups of POSS can be substituted by a functional group through conventional organic conversions. These versatile functional groups, such as methacrylate, acrylate, styrene, norbornene, amine, epoxy, alcohol, and phenol, to name a few, provide the possibility to incorporate POSS into a polymer chain or network through general polymerization or grafting techniques. In this manner, a large diversity of POSS-polymer architectures can be created by the skilled artisan through basic chemistry techniques. Thus the creation of POSS-functionalized conjugated polymers and POSS-functionalized fullerenes and POSS-functionalized fullerene derivatives used in accordance with this invention will be readily apparent to those of ordinary skill in the art.

Because the POSS may be functionalized at its periphery in many different ways, the overall property of the POSS-functionalized entities can be facilely tuned to meet the processing requirements for a given application and to control the heterojunction blend morphology. For example, the introduction of hydrophilic groups to POSS, such as carboxylic acid groups, can make the hybrid hydrophilic and thus can be processed conveniently in alcoholic solutions. The introduction of fluorinated chains to POSS can lead to the self-assembly of the hybrid to the surface of the heterojunction blend.

The conjugated polymers used in this invention may be selected from virtually any conjugated polymer. In those heterojunction mixtures wherein the conjugated polymer is functionalized with POSS, virtually any conjugated polymer may be selected for functionalization.

In some embodiments, the conjugated polymer is selected from poly[[[(2-ethylhexyl)oxy]methoxy-1,4-phenylene]-1,2-ethenediyl] (MEHPPV), polythiophene (PT), and other more recently developed low-band-gap polymers such as poly[(4,4′-bis(2-ethylhexyl)dithieno[3,2-b:2′,3′-d]silole)-2,6-diyl-alt-(4,7-bis(2-thienyl)-2,1,3-benzothiadiazole)-5,5′-diyl] (SiPCPDTBT).

In embodiments wherein the heterojunction includes a POSS-functionalized conjugated polymer, the POSS may be attached at one or at both ends of the conjugated polymer. To functionalize the conjugated polymer with the POSS, both “growing-from” and “grafting-to” approach can be used. The “growing-from” approach is mainly used to synthesize polymers with one POSS at the chain end while “grafting-to” approach can be used to synthesize polymers with two POSS at the chain end or POSS tethered along the chain. A POSS-containing functional monomer can also be used to synthesize polymers with POSS as the side-chain. Methods to synthesize conjugated polymers including Grignard coupling, Wittig reaction, Suzuki coupling, and other metal-catalyzed cross-coupling reactions.

The fullerenes and fullerene derivatives may be selected from virtually any fullerene of fullerene derivative. In those heterojunction mixtures wherein the fullerene or fullerene derivative is functionalized with POSS, virtually any fullerene or fullerene derivative maybe selected for functionalization.

In some embodiments, the fullerenes or fullerene derivatives are selected from [60]fullerene, [70]fullerene, and [84]fullerene and derivatives thereof. The most prevalent fullerene is C₆₀, also known as buckyball since it resembles the shape of a soccer ball. Different numbers of carbon atoms are also possible, such as C₇₀, C₇₆, C₈₄. An exemplary derivative is phenyl-C₆₁-butyric acid methyl ester (known by the common abbreviation PCBM).

In embodiments wherein the heterojunction includes a POSS-functionalized fullerene or POSS-functionalized fullerene derivative, the POSS may be attached at one or more locations of the periphery of the fullerene or fullerene derivative. To functionalize the fullerene with the POSS, a functional POSS can be directly reacted with pristine C₆₀ or C₆₀ can be first functionalized with some reactive groups (such as alkyne or azide) and subsequently reacted with POSS.

The POSS-functionalized fullerenes or POSS-functionalized fullerene derivatives are soluble in organic solvents. Suitable organic solvents include hexane, tetrahydrofuran, chloroform, dichloromethane, ethyl acetate, toluene and chlorobenzene. This allows the bulk heterojunction to be readily processesed to be introduced to a photovoltaic cell. The solubility allows the bulk heterojunction to be applied to photovoltaic cells by coating/printing technologies including spin-coating, spray-coating, dip-coating, doctor-blade coating, slot coating, dispensing, ink-jet printing, thermal transfer printing, silk-screen printing, offset printing, gravure printing, flexo printing.

As already set forth above, a heterojunction in accordance with this invention includes both a conjugated polymer and a fullerene, wherein one or both of the conjugated polymer and fullerene are functionalized with POSS. These different acceptable heterojunctions are made by blending the different components.

It will be appreciated that, in the heterojunctions of this invention, the electron donor (D) is the conjugated polymer or POSS-functionalized conjugated polymer, while the electron acceptor (A) is the fullerene or fullerene derivative or POSS-functionalized fullerene or POSS-functionalized fullerene derivative. With this understanding, in some embodiments, the ratio of D to A is chosen to be within the range of 1:0.1 to 1:10. In some embodiments, there are 10 parts or less A to 1 part D, in other embodiments, 7.5 parts or less A to 1 part D, in other embodiments, 5 parts or less A to 1 part D, in other embodiments, 3 parts or less A to 1 part D, in other embodiments, 2 parts or less A to 1 part D, in other embodiments, 1 part or less A to 1 part D, in other embodiments, 0.5 parts or less A to 1 part D, in other embodiments, 0.3 parts or less A to 1 part D, and in other embodiments, 0.1 parts A to 1 part D. In particular embodiments, the ratio of D:A is in the range of from 1:0.7 to 1:0.8

The use of the heterojunction in accordance with this invention to create an organic bulk heterojunction photovoltaic cell can follow generally known procedures. The present invention does not touch upon changes to the general bulk heterojuction photovoltaic cell structure, but rather provides new bulk heterojuctions useful in the same way as prior art bulk heterojuctions, though the present bulk heterojuctions perform better similar bulk heterojunctions not including the POSS functionalities. This is shown in Examples herein.

### EXAMPLES

### Synthesis of POSS-C₆₀

The following are referenced in this first example:

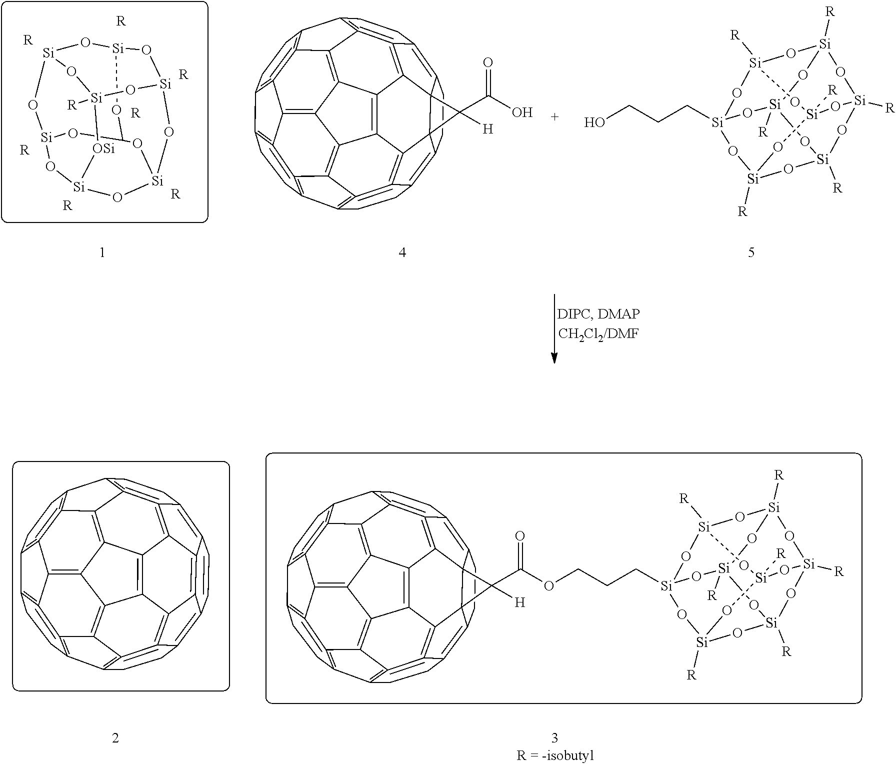

The POSS of formula 1 was functionalized to provide the POSS of formula 5. The fullerene (C₆₀) of formula 2 was functionalize to provide the fullerene of formula 4. The POSS of formula 5 (430 mg, 0.50 mmol), 4-(dimethylamino)pyridine (DMAP, 61 mg, 0.50 mmol) in 8 mL toluene was added To a solution of the fullerene 4 (380 mg, 0.50 mmol) in 16 mL of CH2Cl2/DMF mixed solvent (v/v=15/1), followed by N,N′-diisopropylcarbodiimide (DIPC, 130 mg, 1.03mmol). The mixture was stirred at room temperature for 24 h. After that, the solution was washed with H2O (10 mL) and brine (10 mL). The organic phase was dried over MgSO4 and then concentrated to give crude product. After column chromatography with silica gel using hexane/toluene (v/v=2/1) as eluent, the POSS-functionalized fullerene 3 was obtained as a dark brown powder (572 mg). The dyad POSS-C₆₀ was stable toward singlet oxygen and can be handled without special caution to exclude oxygen. This material is soluble in several solvents, such as hexane, THF, chloroform, dichloromethane and ethyl acetate. Toluene and chlorobenzene are very good solvents with solubility exceeding 300 mg/ml. The functionalization (i-butyl groups) of the POSS component helps increase the interactions with the solvent molecules to achieve this unprecedented solubility.

The dumbbell-like molecule was fully characterized by 1H NMR, 13C NMR, HSQC NMR, MALDI-TOF-MASS, UV-Vis, IR and TGA. All of these results confirm the unambiguous structure of POSS-C₆₀ as proposed.

Yield: 70%. 1H NMR (300 MHz, CDCl3, Figure S1): δ (ppm) 4.80 (s, 1H), 4.45 (t, 2H), 1.98 (m, 2H), 1.89 (m, 7H), 0.98 (m, 42H), 0.83 (m, 2H), 0.64 (m, 14H). 13C NMR (75 MHz, CDCl3, Figure S2): δ (ppm) 148.6, 146.1, 145.8, 145.5, 145.5, 145.4, 145.4, 145.3, 145.0, 145.0, 145.0, 144.9, 144.8, 144.7, 144.2, 144.0, 143.5, 143.3, 143.3, 143.3, 143.2, 143.2, 143.1, 142.7, 142.5, 142.4, 142.3, 141.4, 141.2, 140.8,136.6, 70.9, 68.7, 39.5, 22.5, 8.8. FT-IR (KBr) v (cm-1): 1741 (C═O), 1261 (Si—C), 1229 (C—O), 1099 (Si—O), 524 (C—C in C₆₀). MS (MALDI-TOF): Calcd. monoisotopic mass for C93H70NaO14Si8=1657.3 Da; Found: m/z 1657.8 (100%) (M·Na+).

### POSS-C60—Optical and Electronic Properties

Capacitance-voltage (CV) measurement determined that LUMO of POSS-C60 is −3.94 eV, as shown in the graph of FIG. 2.

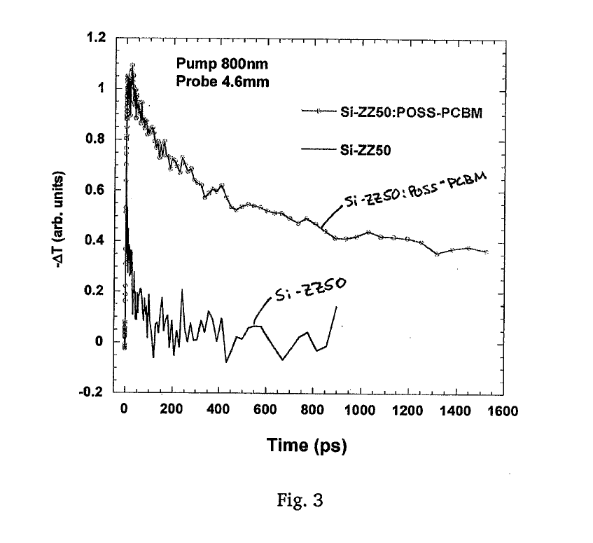

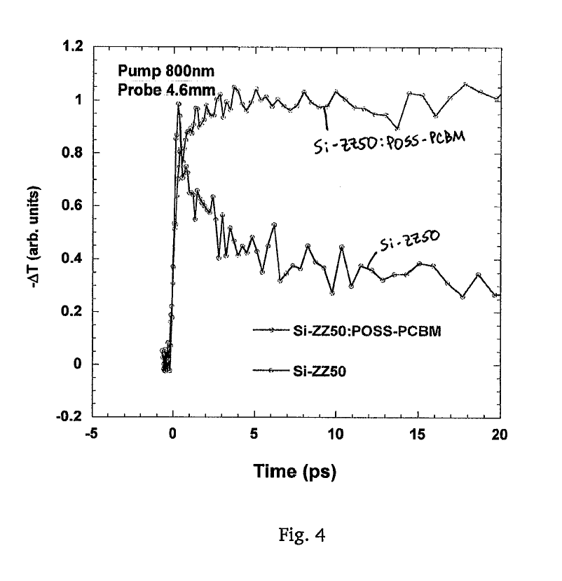

The results observed from time-resolved photo-induced absorption measurement of pristine conjugated polymer, Si-ZZ50, and a composite, Si-ZZ50:POSS-C₆₀ are shown in the graphs of FIGS. 3 and 4. Slow decay from Si-ZZ50:POSS-C₆₀ indicated that POSS-C₆₀ is a good electron acceptor. It will be appreciated that Si-ZZ50 is a generally known conjugated polymer created by Zhengguo Zhu.

### MEHPPV-POSS—Optical and Electronic Properties

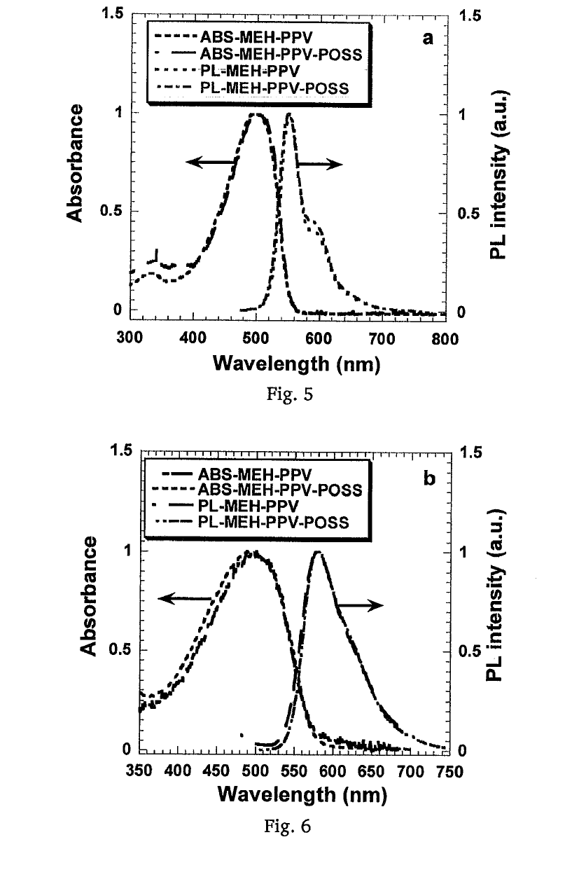

FIGS. 5 and 6 present the ultraviolet-visible spectroscopy (UV-Vis) absorption and photoluminescence (PL) spectra of MEHPPV-POSS and MEHPPV in solution and as thin films. The solutions and thin films were substantially identical but for the POSS functionality so as to focus upon the effect of the inclusion of POSS functionality. Identical absorption and PL spectra are observed for both polymers, either in solution form or as solid thin films. Thus, the introduction of the silsesquioxane segment has no significant effect on the electronic structure of MEHPPV.

### Organic Photovoltaic Cells

(1) Organic Photovoltaic Cells made by MEHPPV-POSS

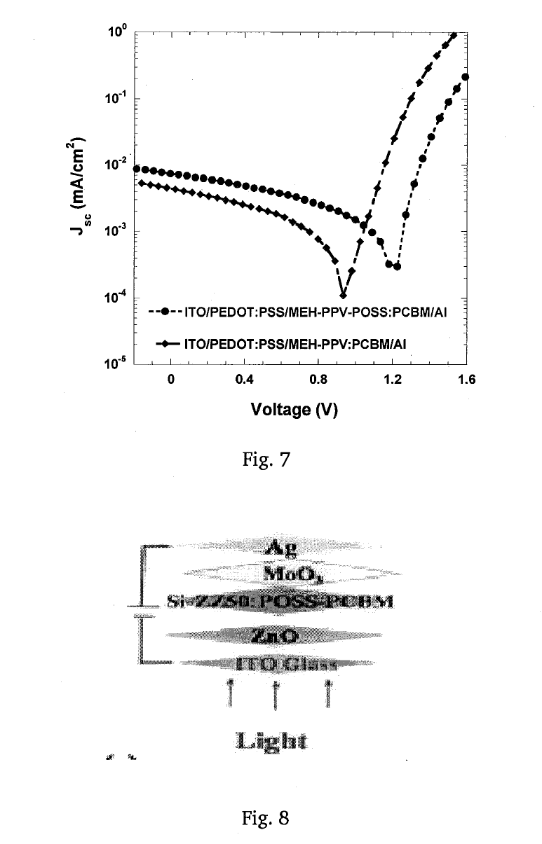

FIG. 7 compares the open-circuit voltage (Voc) of organic photovoltaic cells made by MEHPPV:PCBM and MEHPPV-POSS:PCBM with a device structure of ITO/PEDOT:PSS/active layer/Al, wherein the active layer is in one instance MEHPPV:PCBM and in another MEHPPV-POSS:PCBM. The photovoltaic cells are substantially identical, but for the different active layers, and the acceptor (A) and donor (D) mix ratios are the same so as to focus upon the effect of the inclusion of POSS functionality. Voc increases from approximately 0.9 V to about 1.25 V. Large Voc imply that MEHPPV-POSS significantly enhances the built-in potential in the metal-semiconductor-metal diodes. This is probably due to good adhesion to PEDOT/ITO substrate.

Compared to the polymer solar cells (PSCs) made from MEHPPV:PCBM, PSCs made from MEHPPV-POSS:PCBM have higher short-circuit current (Jsc) and larger Voc, as a result, the high PCEs is achieved. Moreover, the higher thermal stability of MEHPPV-POSS implies that PSCs made from MEHPPV-POSS:PCBM have good operational stability. All these preliminary results indicated that Polymer-POSS will pave a pathway for BHJ PSCs with both high PCEs and good operational stability.

(2) Organic Photovoltaic Cells made by POSS-C₆₀

FIG. 8 shows the inverted device structure of organic photovoltaic cells (OPVs) made by Si-ZZ50 blended with POSS-PCBM.

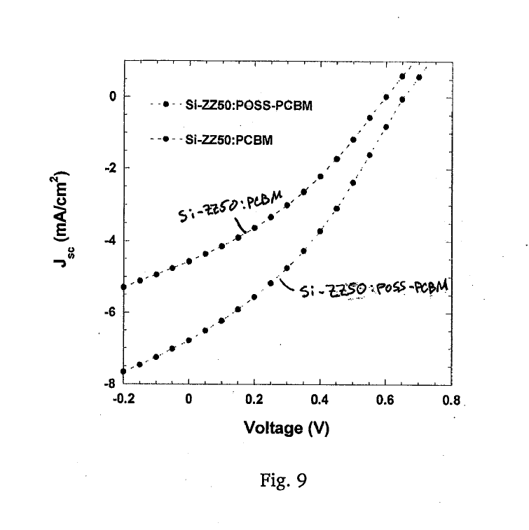

FIG. 9 compares the short circuit current (Jsc) and Voc from organic photovoltaic cells made by Si-ZZ50 blended with POSS-PCBM, and Si-ZZ50 blended with PCBM, with an inverted device structure as shown in FIG. 8. The photovoltaic cells are substantially identical, but for the different active layers, and the acceptor (A) and donor (D) mix ratios are the same so as to focus upon the effect of the inclusion of POSS functionality. The OPVs made by Si-ZZ50 blended with POSS-C₆₀ yields Voc=0.65V, Jsc=6.78 mA/cm2, FF=0.33, as a results, PCE=1.50%. The OPVs made by Si-ZZ50 blended with PCBM yields Voc=0.60V, Jsc=4.56 mA/cm2, FF=0.33, as a results, PCE=0.92%. These results demonstrated that POSS-C₆₀ is a better electron acceptor as compared with PCBM for approaching high performance OPV with an inverted device structure.

In light of the foregoing, it should be appreciated that the present invention significantly advances the art by providing bulk heterojunctions that are functionally improved in a number of ways. While particular embodiments of the invention have been disclosed in detail herein, it should be appreciated that the invention is not limited thereto or thereby inasmuch as variations on the invention herein will be readily appreciated by those of ordinary skill in the art. The scope of the invention shall be appreciated from the claims that follow.

What is claimed is:

1. In a bulk heterojunction photovoltaic cell having a bulk heterojunction that is a mixture of an electron donor and an electron acceptor, the improvement comprising:
functionalizing either the electron donor or the electron acceptor or both with polyhedral oligomeric silsesquioxane (POSS).

2. In a bulk heterojunction photovoltaic cell as in claim 1, wherein the electron acceptor is a fullerene or fullerene derivative.

3. In a bulk heterojunction photovoltaic cell as in claim 1, wherein the electron donor is a conjugated polymer.

4. In a bulk heterojunction photovoltaic cell as in claim 1, wherein the electron acceptor is a fullerene or fullerene derivative and the electron donor is a conjugated polymer.

5. In a bulk heterojunction photovoltaic cell as in claim 4, wherein the electron acceptor is functionalized with POSS.

6. In a bulk heterojunction photovoltaic cell as in claim 4, wherein the electron donor is functionalized with POSS.

7. In a bulk heterojunction photovoltaic cell as in claim 4, wherein the electron acceptor is functionalized with POSS and the electron donor is functionalized with POSS.

8. In a bulk heterojunction photovoltaic cell as in claim 4, wherein the electron acceptor is a fullerene or fullerene derivative, and the electron donor is a POSS-functionalized conjugated polymer, the conjugated polymer selected from poly[[[(2-ethylhexyl)oxy]methoxy-1,4-phenylene]-1,2-ethenediyl] (MEHPPV), and poly[(4,4′-bis(2-ethylhexyl)dithieno[3,2-b:2′,3′-d]silole)-2,6-diyl-alt-(4,7-bis (2-thienyl)-2,1,3-benzothiadiazole)-5,5′-diyl] (SiPCPDTBT).

9. In a bulk heterojunction photovoltaic cell as in claim 4, wherein the electron donor is a conjugated polymer, and the electron acceptor is a POSS-functionalized fullerene or fullerene derivative, the fullerene or fullerene derivative selected from [60]fullerene, [70]fullerene, and [84]fullerene and derivatives thereof.

10. In a bulk heterojunction photovoltaic cell as in claim 4, wherein the electron donor is a POSS-functionalized conjugated polymer, the conjugated polymer selected from poly[[[(2-ethylhexyl)oxy]methoxy-1,4-phenylene]-1,2-ethenediyl] (MEHPPV), polythiophene (PT), and poly[(4,4′-bis(2-ethylhexy)dithieno[3,2-b:2′,3′-d]silole)-2,6-diyl-alt-(4,7-bis (2-thienyl)-2,1,3-benzothiadiazole)-5,5′-diyl] (SiPCPDTBT), and the electron donor is a conjugated polymer, and the electron acceptor is a POSS-functionalized fullerene or fullerene derivative, the fullerene or fullerene derivative selected from [60]fullerene, [70]fullerene, and [84]fullerene and derivatives thereof.

11. In a bulk heterojunction photovoltaic cell as in claim 1, wherein the bulk heterojunction is solution-processed.

12. In a bulk heterojunction photovoltaic cell as in claim 11, wherein the bulk heterojunction is introduced to the photovoltaic cell by coating/printing technologies including spin-coating, spray-coating, dip-coating, doctor-blade coating, slot coating, dispensing, ink-jet printing, thermal transfer printing, silk-screen printing, offset printing, gravure printing, flexo printing.
